(19) United States
(12) Patent Application Publication
(10) Pub. No.: US 2006/0138397 A1
(43) Pub. Date: Jun. 29, 2006

(54) Manipulation of conductive and magnetic phases in an electron trapping semiconducting

(76) Inventor: Daniel C. Mattis, Salt Lake City, UT (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/356,567

(22) Filed: Feb. 17, 2006

Related U.S. Application Data
(63) Continuation-in-part of application No. 10/737,178, filed on Dec. 16, 2003, now Pat. No. 7,045,811.
(63) Continuation-in-part of application No. 11/122,948, filed on May 5, 2005.
(60) Provisional application No. 60/433,738, filed on Dec. 16, 2002.
(60) Provisional application No. 60/568,381, filed on May 5, 2004.

(51) Int. Cl. H01L 29/06; H01L 27/14; H01L 31/109

(52) U.S. Cl. 257/15; 257/428; 257/14; 257/20

(57) ABSTRACT

A semiconductor strip array that can be configured to exhibit distinct electrical and/or magnetic phase characteristics according to the many-body effects phenomenon in electron gases is disclosed. The strip array can be incorporated into a MOSFET architecture and utilized in amplifier and memory cell applications. Significantly, the strip array can exhibit superconductive characteristics under relatively high temperature conditions. In one embodiment, the strip array comprises a grounded substrate, a plurality of strips deposited on the substrate in an intersecting pattern to define the strip array, an insulating layer atop the array, a source, and a drain. The intersecting strip array defines primary electron trapping sites at the strip intersections and secondary electron trapping sites on the strips between the intersections. The strip array is further configured to exhibit distinct electrical and/or magnetic properties according to a selective concentration of electrons injected into the primary and secondary electron trapping sites.

### RELATED APPLICATIONS

This application is a continuation-in-part of the following U.S patent applications: application Ser. No. 10/737,178, filed Dec. 16, 2003, and entitled “Signal Amplification Using Architectures of Nanodots and Connecting Channels,” which claims the benefit of provisional Application No. 60/433,738, filed Dec. 16, 2002; and application Ser. No. 11/122,948, filed May 5, 2005, and entitled “Artificial Ferromagnetism in Semiconducting Arrays,” which claims the benefit of provisional Application No. 60/568,381, filed May 5, 2004. Each of these applications is incorporated herein by reference in its entirety.

### BACKGROUND

1. Technology Field

The present invention generally relates to semiconductive nanostructures. In particular, the present invention relates to a semiconductor strip array that is configured to be modified so as to exhibit varying electrical and magnetic properties based on electron concentration.

2. The Related Technology

Nanotechnology is rapidly evolving field. The race is on to develop self-organizing structures that can be used as active circuit elements. For example, known art has disclosed a process that traps electrically switchable molecules between crossed wires only a few atoms wide, allowing for the creation of a manufacturable molecular electronic technology. There is also currently a great deal of interest in quantum dots, which are three-dimensional heterostructures measuring about 1 nm (10⁻⁹ m) to about 100 nm in each direction, in which electrons, holes and/or excitons may be confined.

Superconductivity, a low temperature phenomenon (T<25 K) that is found in some poorly conducting metals (Pb, Sn, Hg, Nb, etc.) and their alloys, was discovered a century ago. A fundamental theory was lacking until 1957 when Bardeen (also co-inventor of the transistor), and his students Cooper and Schrieffer developed the Bardeen-Cooper-Schrieffer (BCS) electron-pairing theory that is at the heart of our present-day understanding. In 1986, Berdnoz and Müller found the first “high-temperature superconductor” (HTS), capable of superconductivity at temperatures some 50% higher than the previous best and believed by many researchers to be ultimately capable of exceeding room temperature (20° C.) in future developments. The pairing is similar but the mechanism that causes pairing appears to be novel. Unlike “low” temperature superconductors, the HTS have been found to-date only in the layered CuO₂ planes that can occur in crystals of the perovskite type. When each CuO₂ unit contains precisely 5 active electrons, the collective behavior is that of a single spin 1/2. Each CuO₂ plane resembles a spin 1/2 Heisenberg antiferromagnet, weakly coupled from plane to plane. Even such weak coupling allows for a Néel temperature of up to 1000 K, indicating that the in-plane coupling parameter J is substantially related to the substantial. When electrons are taken away, say a fraction f is removed (f is typically in the range of 5%-25%,) a fractionf of the CuO₂ units will acquire spin 0 and a charge +e relative to the other units. This missing electron is called a hole. The presence of holes allows metallic conductivity and superconductivity in CuO₂.

Experimentally the BCS energy gap is not isotropic across the Fermi surface in HTS as it is in the low-temperature superconductors, but has nodes corresponding to so-called “d-waves.” The study of many-body systems (e.g., Hubbard model, t-J models) has indicated that holes promote electronic conductivity and superconductivity, that HTS is mediated by the same antiferromagnetic forces measured by J as the antiferromagnet, and that the gap should have d-wave symmetry. However, there is complete disagreement and confusion in the physics community regarding the precise mechanism and the exact model parameters that apply.

Computer simulations of the Hubbard and t-J models have failed to be definitive, owing to the difficulty of solving the many-fermion problem on a sufficiently large lattice—even approximately.

Memory elements are traditionally dichotomic—such as spin “up” or “down.” In giant magnetoresistance (GMR,) a current is modulated by whether two magnetic fields applied to two nearby conducting elements are parallel or antiparallel. But this set-up is difficult to miniaturize, as the power expended in electrical currents can quickly exceed the ability of the material to dissipate and causes meltdown when circuit elements are densely packed.

Microdots have been made out of specially designed semiconductors embedded in a host material. They trap from 1 to 100 electrons, or valence band holes, or combinations of both called “excitons.”

Field effect transistors (FET) are commonly used for weak-signal amplification, d-c switching or signal generation. In a MOSFET (metal-oxide semiconductor FET), the conductivity of a channel is affected by transverse voltage applied at a gate. This metallic gate, acting across a metal-oxide insulating layer, capacitatively charges the channel, thus affecting its conductivity. The gate in the MOSFET has a high input impedance, therefore low input power. The modulation of the channel width by the gate voltage can be large, therefore there is a large output current and power gain inherent in such devices. If the oxide layer is very thin the electrical fields are high, further optimizing the amplification. But thin dielectrics are fragile, breaking down at or less than 10⁶ v/cm. This limits the ability to modulate charge density by capacitative structures in conventional MOSFETs.

### BRIEF SUMMARY

The present invention has been developed in response to the above and other needs in the art. Briefly summarized, embodiments of the present invention are directed to a semiconductor strip array that can be configured so as to exhibit a number of distinct physical phases, each of which has its own distinct electrical and/or magnetic characteristics. The strip array can be incorporated into MOSFET geometry and utilized in amplifier and memory cell applications. Significantly, the strip array can exhibit superconductive characteristics under relatively high temperature conditions. In one embodiment, the strip array comprises a substrate and a plurality of strips deposited on the substrate in an intersecting pattern to define the strip array. The intersecting strip array defines primary electron trapping sites at the strip intersections and secondary electron trapping sites within the individual strips, half-way between intersections. The strip array is further configured to exhibit distinct electrical and/or magnetic properties, strictly as a function of the concentration of electrons that are introduced into the primary and secondary electron trapping sites respectively, regardless of the means by which these electrons are introduced. This concentration of extraneous electrons can be varied continuously by external means, from zero to several electrons per cell. As the electron concentration is varied, a number of distinct insulating conductive, semiconductive, and superconductive states can be realized.

In another aspect of the present invention, a method for changing the electromagnetic properties of a semiconductor strip array is disclosed. The strip array includes a plurality of intersecting strips of semiconductor material deposited on a substrate. The intersections of the strips define primary electron trapping sites, and the portions of the strips between the strip intersections define secondary electron trapping sites. The method for selectively changing the electronic properties of the strip array includes the introduction (by whatever means) of a quantity of electrons into the array, e.g. so that a portion of the primary electron trapping sites—say 10% to 70% of them—are occupied by electrons. This will cause the strip array to exhibit a first—quasi-metallic—phase. As the density of electrons in the strip array is further increased such that relatively more electrons occupy the sites, a second physical phase will appear, distinct from the first phase. And as more electrons are added, other distinct phases, each with its own electrical and magnetic characteristics, will appear.

In yet another aspect, a MOSFET structure is disclosed that comprises a substrate, and a semiconductor strip array including intersecting strips of semiconductor material deposited on the substrate. The strip array is configured to define primary electron trapping sites at the strip intersections and secondary electron trapping sites at portions of the strips between the strip intersections. An insulator is included above the strip array, and a source, a drain and gate are included above the insulator. A variation in the gate voltage in the MOSFET will cause the concentration of electrons in the semiconductor to change correspondingly. At a low concentration of electrons a quasi-metallic conductivity will be established in the semiconducting strip array; varying the gate voltage further will change the conductivity until a distinct second electronic phase occurs. And as the voltage is further varied such that more electrons are added, other distinct phases, each with its own electrical and magnetic characteristics, will appear. These phases are distinguished by their electrical characteristics, magnetic characteristics, or both. One especially significant achievable phase is superconductivity at relatively high temperatures, a feature that holds promise for current and future superconductivity applications. In addition to insulating or semiconducting or metallic or superconductive properties, some achievable phases will exhibit spatial order in the electrons' spins. These phases, and the ability to go in and out of them at will, by varying an external voltage (thereby varying the electron concentration,) hold promise for future applications in spintronics.

These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof that are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 is a schematic depiction of the geometry of an artificial atom of the present invention having a single circular node connected to a pair of channels, all of a constant depth;

FIG. 2A is a schematic depiction of a right angle bend in a channel, also capable of localizing an electron at the bend, as shown by cross-hatching;

FIG. 2B is a schematic depiction of a right-angle intersection of four channels according to another embodiment of the invention, and it can be shown that when an electron is introduced into this geometry, it preferentially becomes localized at or near the node;

FIG. 2C is a schematic depiction of a channel with a sharp bend according to a further embodiment of the invention, also capable of localizing an electron at the bend;

FIG. 3A is a schematic depiction of an artificial molecule with a dumbbell configuration according to an embodiment of the invention;

FIG. 3B is a schematic depiction of an artificial molecule with a triangle configuration according to another embodiment of the invention;

FIG. 3C is a schematic depiction of an artificial molecule with a square configuration according to a further embodiment of the invention;

FIG. 4 is a schematic depiction of a triangular lattice molecular grid, such as an array that is formed with a plurality of base triangle structures as depicted in FIG. 3B;

FIG. 5 is a schematic depiction of a kagome lattice molecular grid or array that is formed with a plurality of base triangle structures such as depicted in FIG. 3B;

FIG. 6 is a schematic depiction of a square lattice molecular grid that is formed with a plurality of base square structures such as depicted in FIG. 3C;

FIG. 7 is a schematic depiction of one square of a “decorated” square lattice molecular grid that is formed with a plurality of such squares;

FIG. 8 is a schematic depiction of one embodiment of a ferromagnetic array in a square lattice molecular grid showing the layout of intrinsic semiconductor spheres with interconnecting cylinders;

FIG. 9 is a schematic depiction of the ferromagnetic array of FIG. 8, showing the relative spins and charges when the electron number is slightly less than 1 per bubble on average;

FIG. 10 is a schematic depiction of another embodiment of the invention having branching structures, showing the relative spin orientation of two electrons bound at two neighboring branch junctions;

FIG. 11 is a schematic depiction of a further embodiment of the invention having an elementary branching network, with a “bipartite” cluster of sites randomly or arbitrarily connected to one another;

FIG. 12 is a graph showing the calculated “effective” ferromagnetic coupling constant J* vs. kT, both in units of the antiferromagnetic coupling constant J, according to two distinct scenarios;

FIG. 13 is a simplified top view of a semiconducting strip array according to one embodiment of the present invention;

FIG. 14 is a simplified side view of a MOSFET structure incorporating aspects of the present invention according to one embodiment;

FIG. 15 is a graph depicting various phases made possible with the strip array structure shown in FIG. 13;

FIGS. 16A-16F depict various cross-sectional views of a strip of the semiconducting array according to possible embodiments of the present invention;

FIG. 17 is a graph showing the relationship between transverse energy of an electron in such strips vs. base angle of the possible triangular shapes shown in FIGS. 16A-16F; and

FIG. 18 is a simplified side view of a MOSFET structure including multiple strip arrays in a “sandwich” configuration and separated by thin insulating layers, according to one embodiment of the present invention.

### DETAILED DESCRIPTION OF SELECTED EMBODIMENTS

Reference will now be made to figures wherein like structures will be provided with like reference designations. It is understood that the drawings are diagrammatic and schematic representations of exemplary embodiments of the invention, and are not limiting of the present invention nor are they necessarily drawn to scale.

The present invention uses a recently discovered property of particles in narrow spaces as the building block in a new concept for the creation of synthetic structures to make artificial atoms and molecules. The terms “particle” or “particles” used herein refers to subatomic particles such as electrons, photons, excitons, phonons, and the like.

The present invention applies techniques for particle localization by geometrical nanostructures that allow for the production of artificial atoms, and from them, small or large molecules and arrays suitable for use in electronic devices. While the present invention uses procedures based on currently available technologies, it will be understood that the concepts described herein could be applied to technologies developed in the future.

In general, the low-energy motion of particles down a narrow channel becomes one-dimensional if the channel length (L) is much greater than (>>) the channel width (a). In such a regime, a particle can be localized (i.e., made zero-dimensional) at any enlargement (e.g., bends or nodes) of the channel. The binding energy is a geometrically determined fraction of the transverse kinetic energy, and there are no other parameters. This purely geometric effect that shapes the wavefunctions of electrons at low-lying energies helps create new types of quantum dots such as nanodots and artificial lattices.

The artificial lattices made from artificial atoms and molecules can be used to create artificial networks. These can be formed by depositing strips (channels) and nodes (circles or bubbles) of homogeneous semiconductor material on an insulator substrate, and etching away unwanted material to form specific lattice shapes as illustrated in the figures, such as by using photolithographic methods or other techniques.

In addition, artificial electrical conductors can be formed principally in two dimensions, with the sheet resistance controlled by an external, capacitative gate. Artificial two-dimensional electronic superconductors can be formed under certain specified conditions. Field effect transistors and signal- or power-amplifiers based on the preceding may also be produced.

The artificial molecules of the invention can be employed as magnetic memories, with the potential of reading and writing using appropriate, low-energy electromagnetic pulses. Further details of various aspects of the invention are described hereafter.

Artificial Atoms and Molecules

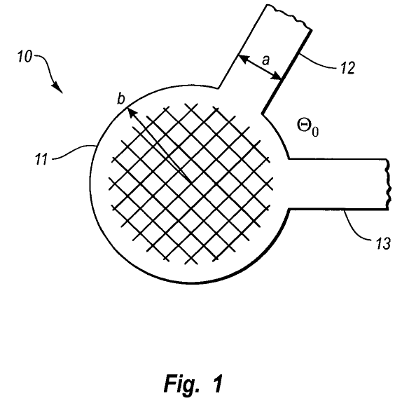

Constrictions in a channel cause reflection of an incident particle but never confinement. Contrariwise, enlargements in a channel, such as a “bubble” or node or the intersection of two or more channels (described with respect to FIG. 1 hereafter), can host a localized bound state lying below the continuum of scattering states. Thus, enlargements in a channel can trap a particle, while constrictions in a channel cannot trap a particle. Theories and theorems that are peculiar to one-dimensional physics are based on elimination of 2 of the 3 spatial dimensions. In practice this could be achieved by guiding the particle through narrow channels, as in a waveguide. The transverse energies are fixed by the transverse dimensions O(a) and are O(nₜᵣ/a)², where nₜᵣ=1,2,3, . . . is a positive integer. If the length of the channel, L, greatly exceeds a, the continuum of low-lying excitations above the fixed transverse energy is ε_{L}=O(n_{L}/L)², with n_{L}=±1,±2, . . . , is characterized as being of the longitudinal type. In the large L limit, the longitudinal excitations form a gapless quasi-continuum rising from each fixed transverse energy. The most consequential of these is the continuum arising from the lowest transverse energy of the particle (at nₜᵣ=1). This lowest transverse energy is denoted herein as ε_{□} and it constitutes the basic unit of energy for our model. Its value is given by: ε_{□}=η²/2m*(π²/a²) with m*=effective mass of an electron in the channels. This result from solving the Schrodinger equation is also compatible with the uncertainty principle; both express the fact that it takes a finite energy to localize an electron within the finite width of a channel. The same holds true for the depth, d, of the channels. However, if the semiconductor strips all have exactly the same depth, the corresponding energy η²/2m*(π²/d²) is a “constant of the motion” that can be disregarded in all meaningful considerations, does not contribute to localization, etc. In addition, in one embodiment the intersection region where strips cross can be made thicker, thereby increasing d and contributing to localization of the electrons at the intersections.

It has long been thought that the narrower the channel, the more the motion is one-dimensional. This cannot be entirely accurate. According to the Schrodinger equation, which determines the dynamics of quantum particles such as electrons, etc., it is precisely because a longitudinally moving particle carries with it a minimum transverse energy ε_{□} that it can be trapped in regions of rapidly changing geometry, i.e., reduced to zero dimensions. It is useful to think of ε_{□} as a reservoir of energy that, when tapped by purely geometrical structures, can localize a particle.

The present invention deals with geometry. The practical advantages that this provides include: to localize a particle there is no need to alter the chemistry or atomic structure within the confining region, as only the size and shape of the confining region need be varied, making the methods of the invention ideally suited to photo-lithographic, etching, imprinting, electron-beam or photon ablation, and/or other commonly used techniques. The root physical cause of the effects of the invention are anchored in elementary quantum wave mechanics, as illustrated by the following example and in the sections that follow, and also apply to other wave-like phenomena.

According to the uncertainty principle, if an electron has the choice of being located within a long strip L of width a, or within a bubble (i.e., circle) of sufficiently large radius b, it will, in the ground state, always select the bubble (the details are in Eq. (4) below). This is not due to a lowered potential that attracts the electron, as the potential energy is, by hypothesis, everywhere constant within the confined areas. Rather, it is that for sufficiently large b the kinetic energy associated with being localized within the bubble, ε_{bubb}≦η²(2.405 . . . )²/2m*b², is less than the minimum kinetic energy in the channel, ε_{□}=η²π²/2m*a². Therefore, in the ground state, the particle has to remain bound to the bubble even when the bubble is connected to the channels. In that case the ground state wave function is localized in and around the bubble, decaying exponentially (“tunneling”) into the channels. The length “l” of this “tail” in units of a is inversely proportional to the square root of the binding energy ε_{BE}. Thus, the length of these “tails” can be “tailored” by manipulation of the binding energy ε_{be}, which is a function of b/a only.

One possible geometry for a structure of the present invention is illustrated in FIG. 1, which depicts a “bubble” structure 10 having a single circular node 11 of radius b (i.e., an artificial “atom”) connected to a pair of channels 12 and 13 having width a and positioned at an angle θ₀ with respect to each other. The radius of the circular node can be from about 1 nm to about 100 nm, and preferably from about ⅔ times the width of the channels to about twice the width of the channels. The channels can have a width from about 1 nm to about 100 nm as well, but preferably from about 5 nm to about 50 nm. The circular node 11 is configured to hold one or more particles (e.g., 1 or 2 particles) such as an electron, with the electron confined to the channels or the node. This is indicated schematically by the cross-hatching. When the ratio b/a is sufficiently large, the ground state is well-localized at the node and has short tails (if the ratio is 1 or slightly less than 1, the length of the tails, l, become longer). The structure shown in FIG. 1 provides the building blocks for artificial molecules and arrays. The artificial atoms should be no less than 1 or 2 “tail lengths” apart or else their wave functions “fuse.” The bandwidth in the artificial arrays, as well as the splitting of the bonding-antibonding orbitals in smaller “molecular” arrays, decreases exponentially with the inter-“atomic” separation L, approximately as 8ε_{be} exp-L/l. In this geometry, the results are practically independent of the angle θ₀. The binding energy is expressed as a fraction of the minimum transverse energy ε_{□}. Once this unit is factored out the model is without parameters. Unless and until 2 or more electrons and their Coulomb interaction are considered, there are no additional parameters and binding is a function of the geometry only.

In one embodiment of the present invention, an insulator substrate (e.g., but not limited to, sapphire, quartz, etc.) has channels or strips of an intrinsic semiconductor material with nodes (e.g., but not limited to, indium antimonide (InSb), silicon, gallium arsenide, indium phosphide, germanium) formed thereon. These channels and the nodes that decorate them are all at a constant potential V(r)=−V₀ relative to the insulator background. V₀ need only be sufficiently large (i.e., V₀>ε_{□}) that it can be replaced by the condition that the wave function is ψ=0 at and outside of the channel walls, without significant error. Beyond this requirement, the magnitude of V₀ is irrelevant. However, the product k_{B}T which is the unit of thermal energy with T the (absolute) temperature in degrees K, should always be low compared with ε_{be}, the energy required to ionize the artificial atom. Thus, one design parameter is that ε_{□} exceed 2 or 3 times the value of k_{B}T at which the device is to be operated. By employing optimal physical parameters a and m*, it is possible to raise ε_{□} up to a reasonable fraction of 1 eV, which corresponds to a temperature of 11,000 K, thus allowing devices incorporating the present invention to operate far above room temperature.

Once the chemical and physical composition of the insulating substratum, the semiconductor, and the gate and insulating barrier have been chosen, only the geometry of the nodes and channels remains to be chosen. The practical advantages of the present invention are many. There is little or no need to alter the chemistry or atomic structure within the entire confining region, either to trap a particle or to allow it to wander. Only the shapes and sizes in the geometry need be selected. This method is ideally-suited for its implementation to photolithography or electron microscopy.

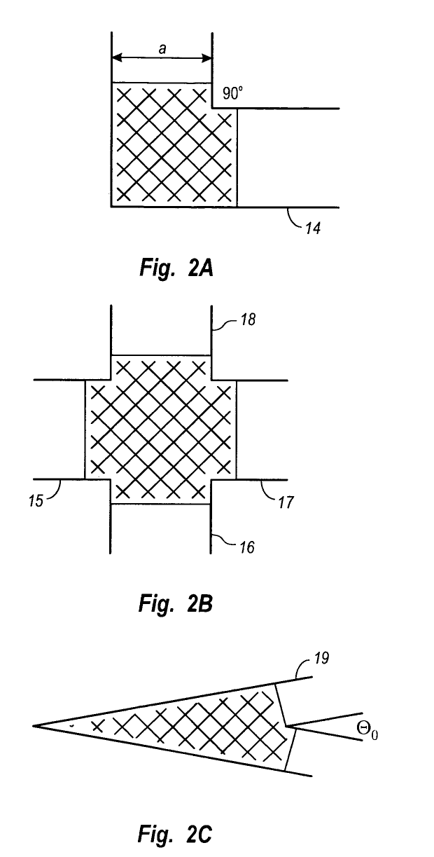

It should be understood that even just a bend or connection in a channel or channels can act as a node capable of trapping a particle, and that a physical circular or spherical structure is not necessary to achieve the effects of particle binding described herein. For example, FIGS. 2A-2C show various channel bends or connections. FIG. 2A depicts a right angle (90°) bend in a channel 14, which has a small but finite binding energy at the corner. FIG. 2B shows a right-angle intersection of four channels 15, 16, 17, and 18 that also results in a bound state at the intersection, while FIG. 2C shows a channel 19 with a sharp acute angle bend (e.g., θ₀<45°), also with a bound state that has a binding energy approaching ¾ times the unit as the angle θ₀ approaches zero.

Consider a single electron inserted into a channel of indefinite length that, at some point, is bent by some angle. The solution of the Schrödinger can be variational: using a simple trial function adapted to the symmetry of the bend it is found that, at some sufficiently acute angles, the optimum variational energy ε₀ lies lower than ε_{□}. In that case, the wave function is anchored at the singularity and decays exponentially into the channel with a characteristic tunneling length

$$\int = \sqrt{\frac{{\tilde{h}}^{2}}{2 m ( {ɛ}_{□} - {ɛ}_{0} )}} = \sqrt{\frac{{\tilde{h}}^{2}}{2 m {ɛ}_{BE}}} .$$

Because the variational solution is not exact, the true ground state has energy even lower than the calculated ε₀, hence a value of l that is somewhat shorter than what is calculated. Thus all parameters in the illustrative examples are to be understood as best-guess estimates. In the example of a square corner (90° bend) shown in FIG. 2A, the quantity f=1.6 a. With the aid of the variational wavefunction, it can be estimated that a substantial fraction, approximately ⅓ of the total probability, is localized in the corner. Details are given immediately below.
The Binding Energy

The variational solution given below applies to the 90° channel bend illustrated in FIG. 2A. In the corner region (x and y both >0) we assume a trial function Ψ_{I}(x,y)=sin(πxy/a²) while in the horizontal channel we taker, Ψ_{II}=sin(πy/a)exp(−q(x−a)), and similarly the vertical channel, upon exchange of x⇄y. For the 3^{rd} dimension we take a constant depth d, thereby increasing the ground-state energy by a minimum constant amount

$${ɛ}_{d} = \frac{{\tilde{h}}^{2} {π}^{2}}{2 {m}^{*} {d}^{2}} .$$

But unless and until we also vary the depth of the channel and/or that of the bend (kinks), ε_{d} remains an ignorable constant of the motion. With this simplification the theory is effectively restricted to 2 spatial dimensions and all energies given are relative to ε_{d}. Similar results can be obtained when the bend is in a cylindrical tube and need not be repeated here.

Although Ψ_{I} and Ψ_{II} are continuous at x=a, their derivatives are not. Thus the total kinetic energy must take into account the discontinuity in the normal derivatives Ψ that occur at x=a and at y=a. The exact two-dimensional ground-state energy ε₀ is bounded from above as follows:

$${ɛ}_{0} \leq \frac{{ℏ}^{2} {π}^{2}}{2 {m}^{*} {a}^{2}} \times Numerator \text{/} Denominator , \qquad ( 1 )$$

where Numerator=N₁+N₂+N₃ and Denominator=D₁+D₂. These quantities are, respectively,

$$\begin{matrix}{N}_{1} = {π}^{2} {\int }_{0}^{1} ⅆ x {\int }_{0}^{1} ⅆ y ( {x}^{2} + {y}^{2} ) {sin}^{2} ( π xy ) = \frac{{π}^{2}}{3} + \frac{1}{4} \\ \begin{matrix}{N}_{2} = 2 ( {π}^{2} - {( qa )}^{2} ) {\int }_{0}^{1} ⅆ y {sin}^{2} π y {\int }_{1}^{∞} ⅆ x {ⅇ}^{- 2 qa ( x - 1 )} \\ = \frac{( {π}^{2} - {( qa )}^{2} )}{2 qa} , and\end{matrix} \\ {N}_{3} = - 2 {\int }_{0}^{1} ⅆ y sin π y ( - qa sin π y - π y cos π y ) = qa - \frac{1}{2} . \\ Also , {D}_{1} = {\int }_{0}^{1} ⅆ x {\int }_{0}^{1} ⅆ y {sin}^{2} π xy = \frac{1}{2} - \frac{1}{4 π} {\int }_{0}^{1} ⅆ x \frac{sin 2 π x}{x} \\ and & ( 2 A ) \\ {D}_{2} = 2 {\int }_{0}^{1} ⅆ y {sin}^{2} π y {\int }_{1}^{∞} ⅆ x {ⅇ}^{- 2 qa ( x - 1 )} = \frac{1}{2 qa} & ( 2 B )\end{matrix}$$

The integral that appears in D₁ is the only one that could not be performed in closed form. It was evaluated using Mathematica. We then obtain for the ratio ε₀/ε_{□}≡r(qa):

$$r = \frac{1 + qa ( \frac{2}{3} - \frac{1}{2 {π}^{2}} ) + {( qa / π )}^{2}}{1 + qa ( 0.774294 … )} \qquad ( 3 )$$

The optimal (i.e., lowest) value of this expression is at qa=0.628293 . . . , hence f=1.6 a. This yields r=0.96000 and in turn, a small but nonvanishing variational binding energy ε_{BE}=0.04ε_{□}. This is within a factor 2 of the exact binding energy, which has to be obtained numerically. From the denominator in (3) one infers that a fraction 0.628×0.774/(1+0.628×0.774)˜0.33 of the electron's probability function (|Ψ|²) is localized in the square a×a region. Hence a fraction 0.33 is localized in each of the two adjacent channels within a distance of the order of ∫=1.6 a from the borders of the square. A similar calculation can be performed for the geometry of the right-angle intersection of four channels shown in FIG. 2B.

The fact that a single 90° bend traps the electron is surprising, but it has also been found that a 60° bend binds better than 90° and, in general, that the binding energy increases rapidly as the angle θ₀ in the structure of FIG. 2C becomes more acute. In the limit of a sharp tip (i.e., for θ₀<<45°), the ground state energy ε₀→¼×the unit (independent of θ₀) and ε_{be} tends to a robust limiting value, 0.75 ε_{□}. (This is an exact result, not a best-guess estimate.) The binding of circular nodes connected to strips, as in FIG. 1, is practically independent of the angle θ₀ between incoming and outgoing channels. At given b the binding energy exceeds the following formula: ε_{be}≧η²/2m*(π²/a²−(2.405 . . . )²/b²)→100%ε_{□} at large b.

For channels from about 1 to about 10 nm in width and m*˜m, the free electron mass, the unit ε_{□} is about 30 meV(meV=0.001 eV) to about 0.3 meV. In many semiconductors the effective mass m* is <<m; then the unit is increased by an additional factor m/m*, a ratio that ranges from about 10 to about 100 depending on the semiconductor. Judicious choices of a and m* allows “tuning” ε_{□} from a fraction of an meV, appropriate to liquid He temperatures (one to a few degrees K), up to a theoretical maximum O(1 eV), which is 40 times room temperature as expressed in meV (note—room temperature is approximately 25 meV). While small values of a and m* might be most desirable for practical applications at reasonably high temperatures, broader channels have the advantage of lower noise and greater ease of manufacture.

It is known by those skilled in the art how to grow channels of SiO₂ or TiO₂ of various widths in the range of about 0.5 nm to about 20 nm, using atomic force microscopy (AFM). Atomic Force Microscopy allows for the deposition of atoms and molecules on a surface, one atom at a time to create clusters of various shapes having a dimension of about 1 nm or less. Present-day technology is increasingly capable of improving on these parameters. Lithography or other techniques should ultimately allow industrialization of the structures and devices of the present invention. Antidot lattices are presently routinely made in optics applications on size scales not much greater than what is required and, with ongoing progress in the manufacture of nano-circuit-elements, it is estimated that in the near future they will be easily made on the required size scale.

Artificial Molecules

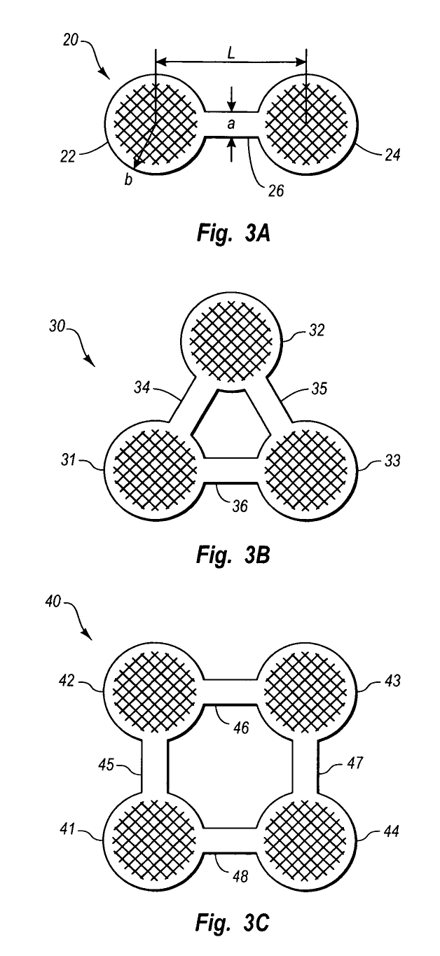

Nonlimiting examples of small artificial molecules that use the bubble structure of FIG. 1 in various lattice configurations are shown in FIGS. 3A-3C. In the “dumbbell” structure 20 of length L illustrated in FIG. 3A, an electron can reside in either or both of two circular nodes 22 and 24, which are communicatively connected by a channel 26 having a width a. The dumbbell structure 20 represents artificial H₂, and each node has a radius b. FIG. 3B shows a “triangle” structure 30 having three nodes 31-33 interconnected by three channels 34-36. FIG. 3C depicts a “square” structure 40 having four nodes 41-44 interconnected by four channels 45-48.

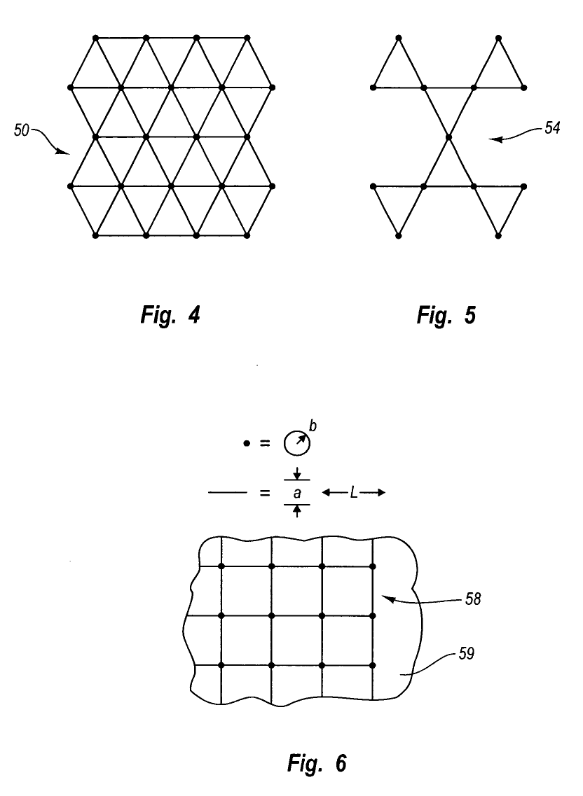

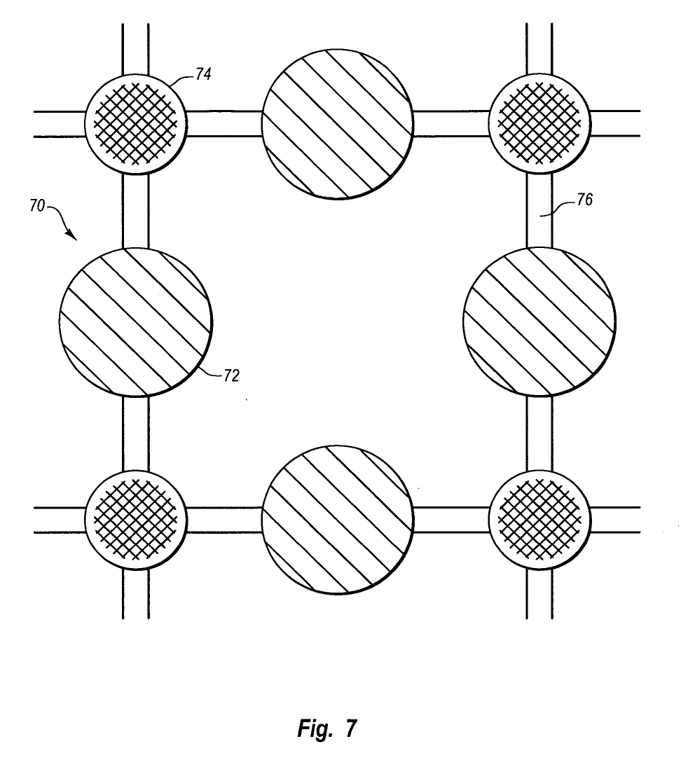

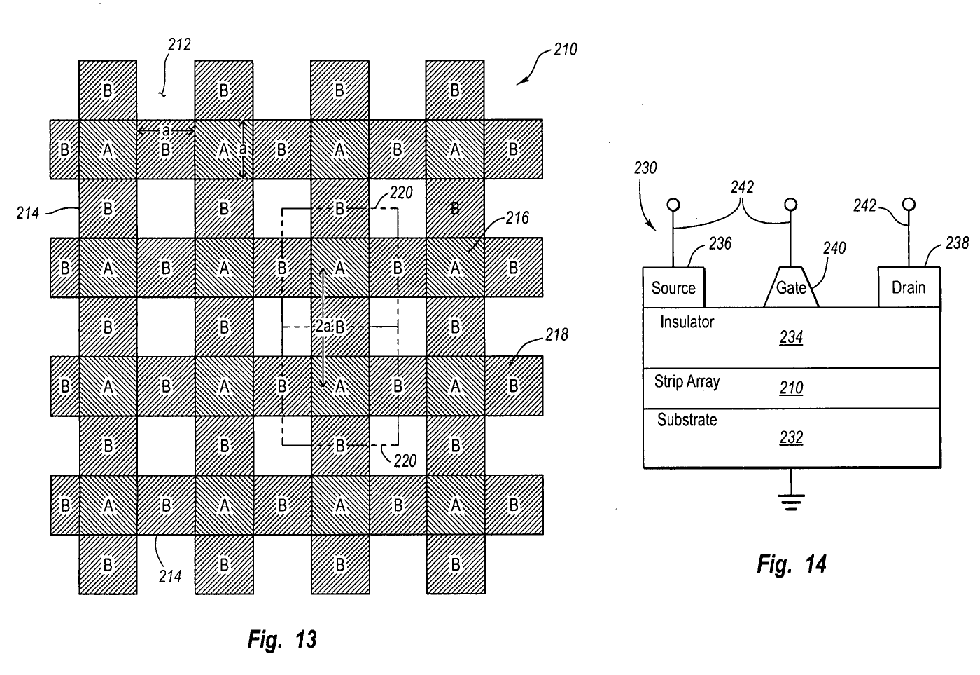

Various molecular grid configurations can be formed by adding additional nodes and channels to produce a variety of molecular arrays of indefinite size that can be viewed as larger artificial molecules. For example, a triangular lattice 50 is shown in FIG. 4, and a kagome lattice 54 is shown in FIG. 5, both of which use a plurality of base triangle structures like that depicted in FIG. 3B. A square lattice 58 is shown in FIG. 6, which uses a plurality of base square structures like that depicted in FIG. 3C. In addition, hexagonal and other lattices are also possible, including irregular structures such as quasicrystals (tiled by triangles and pentagons). In fact, all conceivable two-dimensional lattices can be artificially constructed out of the artificial atoms and molecules of the present invention. The decorated square lattice of FIG. 7 is based on that of CuO₂ planes in the perovskite crystals (YBCuO, LaSrCuO, etc.) in which “high T, superconductivity” is observed. The simplest large arrays or grid configurations (although not that of FIG. 7) can be formed by laying down strips of intersecting semiconductor material over an insulating substrate, such as substrate 59 shown in FIGS. 6 and 13, with a kink or node formed where the ribbons cross, allowing the formation of bound states at each crossing. These coalesce into a “bound-state” energy band of Bloch states, all lying below the unit of energy.

The “hopping” energy 2t* is defined as the splitting between symmetric (“bonding”) and antisymmetric (“antibonding”) orbitals. Ψ_{sym} has a finite “tail” ∝exp −L/2 l, halfway down the channel. Ψ_{antisym} vanishes halfway down the channel. The splitting is typically of the order of t*=ε_{be} exp-L/l. This value is then used in the 2-site “hopping” Hamiltonian, Hₕₒₚ=−t*(c₁+c₂+H.C). Recalling ε_{be}∝(1/l)² we maximize t* with respect to l, obtaining l˜L/2. This in turn determines an optimal aspect ratio L/a such that 2 l<L<4 l. If L is much longer than 4 l, t* will become negligibly small relative to the other parameters in the model. If L is much shorter than 2 l, the localization is lost. In what follows, it is assumed that t* is optimized and the nearest-neighbor distances are all L. There may, however, be good reasons to engineer a smaller value of t* in localized regions where particle itinerancy is undesirable.

The interaction of 2 electrons provides a second parameter, U. If both particles are present at the same node, the Coulomb repulsion is ˜O(e²/2b). In the present units this is:

$$U = \frac{{ⅇ}^{2} 2 {a}^{2} {m}^{*}}{2 {b ( \tilde{h} π )}^{2} κ} = ( \frac{1}{{π}^{2}} ) ( \frac{a}{b} ) ( \frac{a}{{a}_{Bohr}} ) ( \frac{{m}^{*}}{m} ) ( \frac{1}{κ} ) ,$$

where a_{Bohr}˜0.529 Å and κ is the dielectric constant (approximately κ=10 in most semiconductors.) Being neither obviously negligible nor obviously dominant, the Coulomb term is an independent, variable, parameter that is sensitively dependent on the size-scale parameter a. The relevant Hamiltonian is H_{Coul}=U(n₁↑n₁↓+n₂↑n₂↓), where n_{j,}↑=c_{j,}⁺↑c_{j,}↓. Because U>0, the two electrons will reside preferentially on distinct nodes, where the Coulomb interaction drops to a fraction 2b/L of the value of U given above.

In the ground state the spins that are nearest-neighbors should also demonstrate a tendency to be antiparallel. This tendency is measured by an “exchange parameter” J. With an electron at each end 20 of the dumbbell FIG. 3A, the bound states include 1 singlet ground state and a triplet of excited states. The singlet-triplet splitting is

$$J = \sqrt{{( \frac{U}{2} )}^{2} + {( 2 {t}^{*} )}^{2}} - \frac{U}{2} ,$$

so that 0<J<2t*. J appears only in the spin-spin interaction,

$${H}_{sp - sp} = J ( {S}_{1} \cdot {S}_{2} - \frac{1}{4} ) , with {S}_{1} = \frac{\tilde{h}}{2} [ {c}_{1 ↑}^{+} , {c}_{1 ↓}^{+} ] [ {σ}^{τ} ] [ \begin{matrix}{c}_{1 ↑} \\ {c}_{1 ↓}\end{matrix} ] ,$$

etc. It has the appearance of a 2-body attractive force favoring singlets that encourages neighboring electrons to carry antiparallel spins. It should be emphasized that the calculation of J did not invoke any new physical mechanism and that it is not an independent parameter, just a useful one.

Combining terms, with H=Hₕₒₚ+H_{Coul}+Hₛₚ₋ₛₚ for an arbitrary geometric array of nodes connected by channels, and using the familiar tight-binding approximation to the solutions of the Schrödinger equation, we find the array to be governed by one or another modification of the Hubbard or (if we include J explicitly,) the t-J models, both frequently studied and invoked in connection with high-T_{c} superconductivity. One notes a subtle difference, in that a spectrum of delocalized channel states exists here, not very much higher in energy than the family of localized states that encompass the Hilbert spaces of the Hubbard-t-J models. On decorated square lattices such as that of FIG. 7, the singlet states on the artificial oxygen atoms (the “decoration” bubbles on the links) are able to impose their singlet nature onto Cooper pairs in a manner that requires at least a 3-band model and cannot be described by the simpler and less structured Hubbard or t-J models.

Three electrons at the corners of a triangle structure such as shown in FIG. 3B have total spin 1/2 in the ground state (there are in fact two ground states with opposite chirality) and 3/2 in the excited states. Spins in such triangle structures are naturally “frustrated.”

Four electrons localized at the corners of a square structure such as shown in FIG. 3C have total spin zero in the ground state and spin 1 in the lowest-lying excited bound-state configurations. Three electrons in this molecule can have a level crossing from a ground state doublet configuration (minimal spin) to a ground state quartet (maximal spin) at or above a certain value of U, dependent on the scalar dimensions of the bubbles and their connections.

In studying eigenstates of arrays containing fewer than 1 electron per node, both the “hopping” matrix element t* that allows a localized particle to move to a neighboring unoccupied node and the antiferromagnetic coupling constant J that couples the spins of two neighboring electrons are of primary importance. Moreover, t* and J are both of the same order of magnitude, subject to the inequality noted earlier, 0<J<2t*. Interesting quantum states can be created artificially by changing the number of electrons away from the “critical” number of 1 per node. For example, the ground state of a triangle structure containing only two electrons is split to O(t*) into 3 singlet states, corresponding to 3 distinct values of the angular momentum of the missing electron or “hole.”

Antiferromagnetic, Metallic and Superconducting Networks

By connecting individual units of the types shown in FIG. 3A-3C, various geometrical grid arrays or “networks” can be created. For an artificial s=½ antiferromagnet, there must be one electron per bubble (i.e., node or vertex) on the given grid. This can be accomplished by chemical doping of the substratum (e.g., by locating “donor” atoms within the substratum, or depositing a n-doped semiconductor layer above the active network), in conjunction with a metallic gate communicating with the network via a high-resistance layer, as in a MOSFET, to send electrons into the channel. The latter could “fine tune” the former by the capacitance effect.

By such structures, an artificial Hubbard or t-J model on an artificial lattice with adjustable occupation numbers can be constructed. This can be done in one dimension (ID), i.e., on a linear array of bubble nodes of radius b separated by channels of length L and width a containing a variable number of electrons. At partial filling, well-known aspects of the 1D metals can be tested, such as separation of spin and charge, etc. At half-filling, the spin one-half one-dimensional Heisenberg model can be recovered and its well-known properties observed.

With regard to two-dimensional (2D) arrays, since the discovery of T_{c}>30 K superconductivity in LaCuO, numerous other high-T_{c} superconductors of the CuO₂-based perovskite family have been constructed. The highest T_{c}'s are presently just shy of 200 K. Aside from a shared crystal structure, the key elements they all have in common are stacks of square (sq-symmetry) antiferromagnetic arrays, weakly-coupled along the c-axis. Once a sufficient concentration of holes is introduced by alloying, some of these materials trade their antiferromagnetism for high-T_{c} superconductivity (HTS). Over the past decade and a half there have been innumerable attempts to evaluate the correlations in the 2D Hubbard model, to search for the microscopic sources of HTS. This research is still, for the most part, inconclusive. The decorated square lattice of FIG. 7 is an artificially constructed, or “analog”, version of the electronics in a copper-oxide layer and does not require further approximations or much modeling to exhibit properties that are presumably quite similar to the latter.

Additionally, there is an intriguing possibility that the triangular or kagome lattices, whether those of the Figures or “decorated” versions thereof, make even better superconductors. When the occupation number is 1, these are fully frustrated two-dimensional antiferromagnets, hence highly paramagnetic. Because there is not much energy stored in the antiferromagnetic phase, these structures might be optimally unstable against superconductivity when the density of electrons is fractionally higher or lower than the density of nodes. Because CuO₂ is not known to occur either naturally or artificially in planar triangular or kagome lattices, there is no experimental precedent and the superconductivity is just conjectured. Nevertheless, the construction of such “geometrically frustrated lattices” of geometrically localized states does not pose any additional serious technical difficulties.

A particularly useful application is the decorated square lattice 70 in FIG. 7, with the “decoration” spheres 72 (the artificial oxygen atoms) larger than the corner spheres 74 on the vertices (the artificial copper atoms), such that spheres 72 accommodate 2 electrons each while the corner spheres 74 can only accommodate 1 electron each. The spheres 74 have a radius b, and the spheres 72 have a radius b₂. The channels 76 between the spheres have a radius a˜⅔b₁ and length l of approximately b₂. The sizes and connections have to be such that when the electron number is reduced below 5 per cell, the electrons have been primarily removed from the artificial oxygen atoms and not from the artificial copper atoms, just as is believed to be the case in CuO₂ on which this is modeled. To the extent that the artificial atom model emulates the chemistry of CuO₂ planes, one should observe a dramatic change in the resistivity—by many orders of magnitude—when the electron concentration is decreased from 5 per cell to the range 4.8±0.2 and similarly when it is increased from 1 to 1.2±2.

The following shows one possible application of the superconducting phase. It is assumed that through substratum doping, or by tunneling, a fraction of the requisite numbers of electrons is introduced into an artificial network such as we have described. Given the dimensions suggested above, the electron density that is required is low, estimated at typically less than O(10¹²/cm²), i.e., of the order of the density of nodes formed on the surface. Most of the surface consists of the substratum insulator, with only a fraction of it occupied by the active network.

Part of the required number of electrons can be supplied via substratum doping as described in paragraph [−055, 065] herein, but that is a fixed number. By superposing capacitative charging via tunneling, one can further affect the density of electrons, reducing or increasing their number substantially from what was built-in. Now, the value of T_{c} depends on electron density. At densities where the active network transitions rapidly from insulator (at 1, 2, 3, 4 or 5 electrons per unit cell) to a metal or even superconductor (i.e., in the ranges 1.2±0.2, 4.8±0.2 electrons per cell), a small change in the gate voltage can take the network from an insulating or poorly conducting phase to a highly conducting or even superconducting phase, depending on the temperature. In that case, the sheet resistance of the artificial lattice would change by several orders of magnitude. This enormous leverage could be used to create a novel metal insulator superconducting field effect transistor.

Artificial Atoms and Molecules as Memory Elements

The present invention allows the creation of nano-logical elements for low-loss information storage and retrieval. Both the position of an electron at a node and the direction of its spin may be viewed as parameters to be recorded and detected. For example, a triangle structure carrying three electrons with total spin 1/2 has 2 sets of degenerate ground state doublets of energy

$$- \frac{3}{4} J ,$$

plus 4 excited states of total spin 3/2 having energy

$$+ \frac{3}{4} J .$$

As the two sets don't normally mix, the higher-energy spin configurations are metastable. The spin of the triangle could be “read” non-destructively. What is more, low-spin can be transformed into high spin (“rewritten,”) or vice-versa, by the action of a weak a-c field of frequency

$$ω = \frac{3 J}{2 \tilde{h}}$$

or by the passage of a small magnetic pulse. This frequency can be quite high. Existing magnetic memories (MRAM's) have been reported having switching rates approaching 2 Ghz, which at the present time is the state-of-the-art speed for nonmagnetic memories. Static magnetic fields partially lift the degeneracies: the ground states will split into two sets by an amount proportional to the external field B, the excited states into 4 distinct sets by an amount 3 times as great. Crystal anisotropy may further split the states.

In the artificial molecules shown in FIGS. 3A-3C, t* and J can be varied at will by changing the aspect ratio L/a. An external magnetic field B splits the magnetically degenerate states. As these quantities are all adjustable variables, their magnitudes are not specified herein. Thus, assuming 1 electron/node, the ground states of the structures of FIGS. 3A and 3C are unaffected by B while the lowest excited state of each moves down by −B. If B exceeds J, the ground state and first excited state switch identity.

Another example of a permanent memory element is that previously cited, of 3 electrons on the artificial square molecule. If the dimensions are properly chosen such that U is close to, but just below U_{C}, the response to an external magnetic field would be highly nonlinear; a small magnetic field could promote the spin 3/2 state of maximum magnetization at the expense of the usual doublet ground state of spin 1/2 or minimum magnetization. Absent external forces, the resulting spin will remain constant in time.

In any case, a small electromagnetic pulse can probe where the molecule is in its ground state or first excited state, and depending on its length, can also rewrite the state. The eigenstates persist indefinitely until perturbed. Given any small amount of hysteresis, this property allows the artificial atoms and molecules to be used as memory elements.

For the triangle structure, the ground state doublet and the excited state quartet play the same roles as the singlet and triplet states above. The important point, once again, is: eigenstates are stationary, i.e., they persist indefinitely unless perturbed and cost no energy to maintain.

The present invention has the benefits of providing for the potential of making artificial antiferromagnets, memory elements, and high-temperature superconductors out of channeled electrons in two dimensions, entirely without benefit of magnetic ions, using only existing technology. In addition, the invention can be applied to the localization of bosons (e.g., photons, phonons, excitons), in that the sole requirement to localize bosons is that the “cavity” at a node (i.e., the intersection of 2 or more channels) is able to support a normal mode of frequency lower than the bottom of the pass-band of the waveguides (channels) to which the node connects. Unlike electrons, however, these bosons will ultimately dissipate. This helps distinguish bosonic applications from the electronic applications in embodiments of the present invention. For, in an electron device, once the gate voltage is set at some constant value the electron density in each cell is specified indefinitely and forever by “particle conservation.”

The artificial networks of the invention have an electrical resistivity that depends on the concentration of electrons. Near 1 electron per node, an antiferromagnetic insulator is created. With a slightly lower or higher number of electrons, a metallic or superconducting conductivity (low resistance in either case) is produced. A metallic gate that injects electrons into the network (through an insulating layer) sees a high impedance which therefore absorbs very little power. But the small change in voltage results in a large change in the electron concentration within the semiconducting layer, hence a large change in the resistivity of the network plane as seen between source and drain. Thus, a power amplifier or transistor is created.

Artificial Ferromagnetism

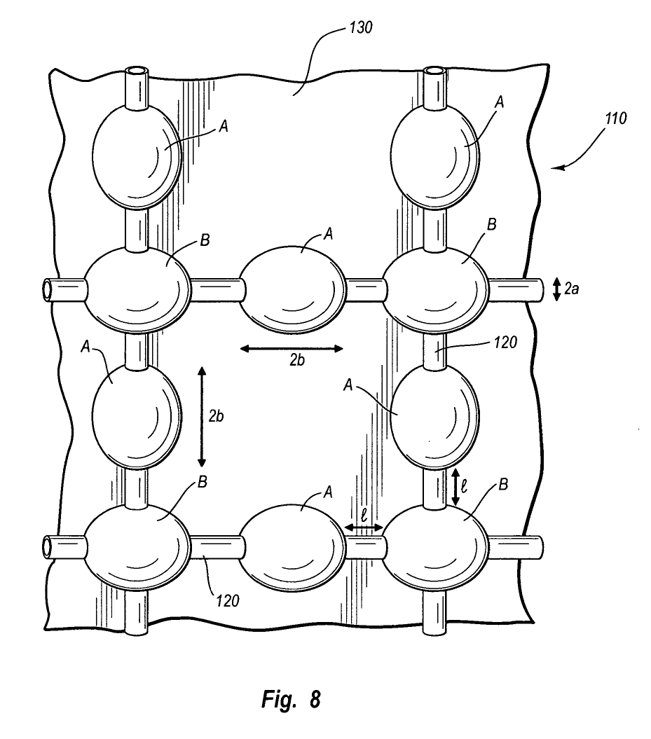

Reference is now generally made to FIGS. 8-12. One of the goals of “spintronics” has been the production and manipulation of spin-polarized electrons in microelectronic circuitry. It has been found in the present invention that magnetically polarized arrays of arbitrary size can be constructed out of nonmagnetic semiconducting material, such as intrinsic silicon laid over an insulator substrate, into which electrons can be injected by standard means: substratum doping or capacitatively.

The present design implements a bipartite lattice with antiferromagnetic exchange interactions. The “bubbles” and “channels” of the present invention, discussed hereafter, have been designed to mimic the parameters of a mathematical model called the Hubbard model insofar as this is possible. The present design is based on a phenomenon of wave mechanics that has only been understood in recent years: the formation of localized states at singularities in electron “waveguides.” Interesting results are also found in one-dimensional arrays, and even three-dimensional arrays, although more difficult to fabricate, are conceptually similar.

The term “bipartite” implies that an electron on an A nanodot site can only “hop” (i.e., be transferred,) to a nearby B nanodot site, and vice-versa, with A to A or B to B hops being prohibited. It can be proved that the ground-state of any such system belongs to total spin moment Sₜₒₜ=(½)|N_{A}−N_{B}| (in units of η). N_{A} and N_{B} are respectively the number of A and B sites, not necessarily equal and not necessarily ordered and M, the total magnetization, is proportional to Sₜₒₜ.

In order to illustrate the invention, a nano-array is specified that, by virtue of Lieb's theorem, must exhibit spontaneous ferromagnetism at or near an electron concentration of 1 per site (this phenomenon is also called ferrimagnetism because of similarity to magnetism naturally occurring in the ferrites.) Other designs that satisfy the conditions that Sₜₒₜ=(½)|N_{A}−N_{B}|≠0 are similar, mutates mutandis. Although the following discussion relates to a two-dimensional array, it should be understood that the present invention can be a one-dimensional array or a three-dimensional array.

In one embodiment, the invention physically includes identical, interconnected, nonmagnetic nanodots made of an intrinsic semiconductor material, such as silicon, indium antimonide, gallium arsenide, indium phosphide, germanium, and the like, organized into N cells in a two-dimensional trellis structure in which N_{A}=2N_{B}=2N. FIG. 8 illustrates the layout of intrinsic silicon spheres (“bubbles”) and silicon cylinders (“channels”) that connect the spheres in one embodiment of a synthetic ferromagnetic array 110. The array 110 emulates the lattice of planar CuO₂, with Cu and O ions replaced by a set of identical spherical objects (bubbles) A and B of radius typically 10 nm (or ranging from 1 to 100 nm,) made of intrinsic semiconducting material. The bubbles are connected by narrower cylinders 120 (channels) made of the same material as the bubbles. The radii, b, of the bubbles and the radii, a, and lengths l of the channels, as illustrated in FIG. 8, are picked to favor electron occupancy of bubbles over channels. The array 110 is formed over an insulator substrate 130, which can be various materials such as sapphire, quartz, and the like. The spheres could be “buckyballs” of carbon connected by channels of carbon nanotubes, and can have a radius of about 1 nm to about 100 nm. The nanodots can have a radius of about 1 nm to about 100 nm, but are generally wider than the channels.

In one example of array 110, the spherical radius b=1.5a, and an optimal cylinder length l=1.683a. The magnitude of a (cylinder radius) is arbitrary—until Coulomb forces and effective exchange interactions are taken into account and optimized. Then it is determined to be in a range of less than about 100 nm, depending sensitively on the semiconductor's dielectric constant, the effective mass of the carriers, and the range of temperatures for operation of the device.

The array 110 shown in FIG. 8 can be fabricated by nanolithography followed by selective etching and vapor deposition. Instead of using ion implantation or chemical doping to introduce electrons into the neutral semiconductor material, subsequent electron doping of the semiconducting layer can be induced by standard capacitative means such as that at the basis of conventional MOSFET devices. The required density of electrons in the present design is quite low and therefore achievable (i.e., on the order of or less than 10¹²/cm²). To the extent that this density of electrons can be modulated by an external electromagnetic field (EMF), the geometry of the array of the invention becomes capable of high signal amplification at low thermal dissipation, both valuable design considerations.

An alternative fabrication approach for the invention generalizes the “virtual” channels that are created in a semiconductor by electrostatic induction using shaped metallic electrodes. Although more difficult to analyze than the present model and less flexible in its device applications, a shaped-metal architecture might prove easier to fabricate than a shaped-semiconductor architecture that serves the same purpose.

The design of the present invention can also be used to make magnetic memory elements, as well as in other applications. As shown in FIG. 8, each bubble is connected by channels to either two or four nearest-neighbor spheres. The spheres that “decorate” the square lattice are assigned to the A sublattice while the corner spheres constitute the B sublattice, an ordinary sq lattice. In an infinite array, the unit cell can be chosen to include one B and two nearest-neighbors A (e.g., one immediately above it and the other immediately to its right.) For exactly 3N electrons (one per bubble and none in the channels), the ground state spin per unit cell is ½ (in units of h-bar) so that for N cells there can be a magnetic memory element corresponding to a spin N/2. Lowering the number of electrons to somewhat fewer than 3 per cell or raising the number of electrons to somewhat more than 3 per cell will lead to metallic phases and loss of magnetic moment. The changeover to a nonmagnetic phase is accompanied by a large change in electrical sheet resistance.

The present disclosure has assumed use of a semiconductor that is induced to be n-type by injection of electrons. But by symmnetry, the word “electron” also can be replaced by “hole,” the charge carrier in the valence band of semiconductors, if the semiconductor is induced to be p-type by injection of holes.

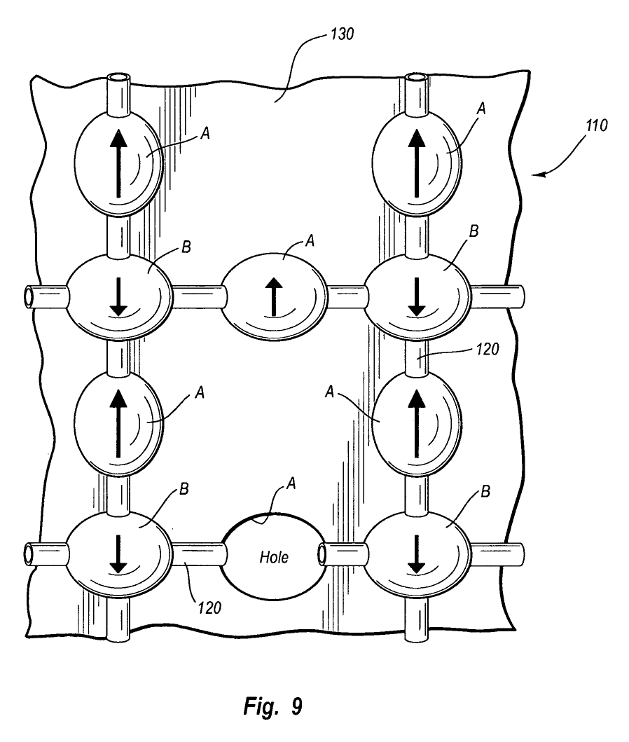

FIG. 9 depicts the ferromagnetic array 110 of FIG. 8, showing the relative spins and charges when the electron number is slightly less than 1 per bubble on average. A “hole” (a missing majority electron of spin 1/2) shown in FIG. 9 on an A site, is unstable on B sites but can tunnel (after a 15-step “ring exchange” that leaves no “string” behind) onto a diagonally neighboring A site, thereby exhibiting incipient metallic conduction along the (1,1) axes. A nearest-neighbor exchange mechanism suggests looking for metallic conductivity when the number of electrons per cell is sufficiently reduced below 3 or raised sufficiently above it for the ferromagnetic order to be squelched.

Specific solutions of the Schrodinger equation allow for the optimization of values for the parameters a, l, and b such that electrons are localized principally in the bubbles and not in the channels that connect them. The idealized ferromagnet of this design is an electrical insulator, because the on-site Coulomb interaction is sufficiently strong to discourage charge fluctuations (as in the “Coulomb blockade” in the standard example of a single microdot). Alterations in the architecture—specifically in the connectivity—can produce an ordered antiferromagnet (Sₜₒₜ, =0) instead. Reduction in electron concentration to fewer than 1 electron per bubble should cause metallic charge transport to occur.

In addition, the present invention includes a method for insulator-to-metallic transition that allows for signal and power amplification when the semiconductor array is imbedded in MOSFET geometry. The insulator phase exists at or near electron concentrations per unit cell of v=1. The phase transition to a metallic phase occurs at or below an average electron concentration v_{c′} (where v_{c′}<1). For more than 1 electron per bubble it occurs when v is at or near v_{c′}, where v_{c′}>1). By biasing the value of v near v_{c} or v_{c′}, it is possible to increase the sensitivity of the conductivity of the semiconductor material by a large factor through small external changes in bias voltage that changes the actual value of v.

When the present invention is employed in a memory element, small arrays will have a permanent magnetic moment M=m₀|N_{A}-N_{B}| until the value of v is changed sufficiently (“erasing” by raising or lowering v) that Sₜₒₜₐₗ→0. Thus, the magnitude of the magnetic moment can be used as a memory element, instead of or in addition to its orientation.

In general, wherever a nanotube branches out, such as a carbon nanotube does in carbon nanofoam, an electron trap is created inside (at or near) the junction. Electrons occupying neighboring junctions align their spins antiparallel. If there are more sites on sublattice A than on the interpenetrating sublattice B, the net result is M=m₀|N_{A}-N_{B}|.

Ferromagnetism is produced in these structures because of: (1) the presence of channels that allow electrons to move; (2) the formation of bound states at singularities in the channels (e.g., at a branching of one channel into two, or at a bulge or bend in any given channel); (3) the antiferromagnetic correlations of two electrons trapped on nearby bound states; and (4) an unequal number of sites on two interpenetrating sublattices that contain electrons of spin up and down respectively.

Formation of Bound, Localized States and their Interactions

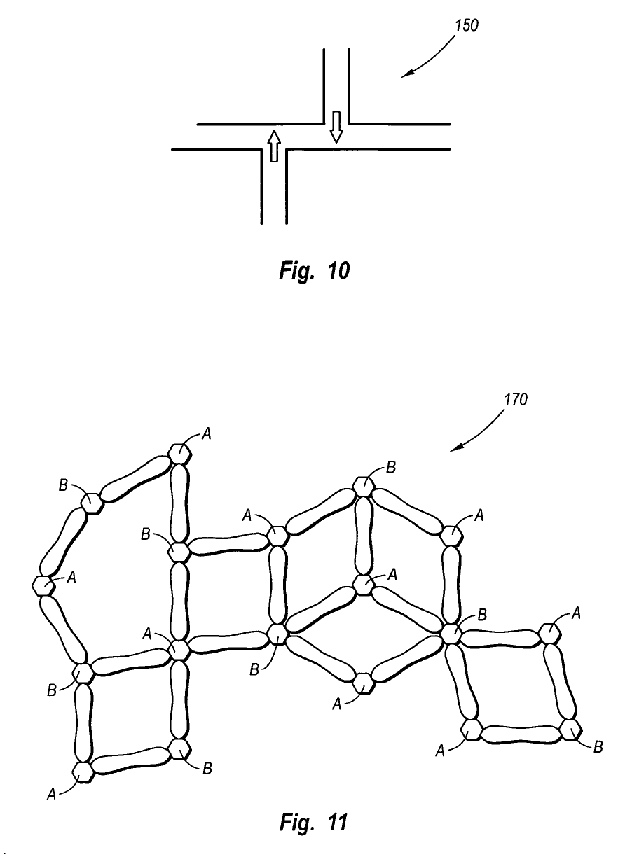

Bulges, bends or branching in a hollow tube, in which mobile electrons are confined (subject to boundary conditions Φ=0 on the surfaces), naturally cause the appearance of a bound state that is localized at the bulge, bend or branch. For example, a pair of branching “tee” structures 150 is illustrated in FIG. 10, showing the relative spin orientation of two electrons bound at the neighboring branch junctions (“tees”). Assuming the minimum energy of an electron confined in the channels is ε₀=η²π²/2ma² (a=diameter), we find the energy of a bound state at the bifurcation ε_{b} to be lower in the amount ε₀-ε_{b}=ε₀×0.35356, and the singlet-triplet splitting J of two bound electrons at a distance 2 a apart to be approximately J=170 k_{B} (in temperature units). For example, when a˜6 nm for the diameter of the nanotube, the allowed energies form a continuum ε₀+η²q²/2m above the minimum energy, where ηq is the longitudinal momentum along each channel. Additionally, a unique localized state is formed at each “tee” structure. The energy is calculated using WKB. A bound state is substantially lower than the minimum channel energy, i.e., ε_{b}=ε₀×0.6464 for this geometry.

The triplet-singlet splitting of 2 electrons trapped on two neighboring “tees” a distance 2a (12 nm) apart can be calculated as follows: the energy of the antisymmetric, antibonding orbital is ε₀×0.6648 while that of the symmetric orbital is ε₀×0.6307, yielding an effective “hopping matrix element” t=ε₀×0.017. The “Hubbard U” is estimated at e²/2a=ε₀/π², therefore J=4t²/U=ε₀×0.0114. With ε =15000 k_{B} in ⁰K, the other correspond roughly to U=1500 k_{B}, t=250 k_{B} and J=170 k_{B}; all are reasonable “ballpark” figures for this physical system, the dynamics of which can be described by an antiferromagnetic Hamiltonian, H_{1,2}=JS₁·S₂.

As can be seen, whenever two nearest-neighbor trapped electrons interact, their joint singlet state is always favored over the triplet. With splitting defined as J, a standard estimate is J=4t²/U, where t is the “hopping” matrix element defining the overlap of the single particle wavefunctions at the two sites and U is the Coulomb repulsion when both occupy the same site. Thus, perhaps paradoxically, ferromagnetism is triggered by antiferromagnetic bonds J. FIG. 11 shows a two-dimensional version of an elementary branching network 170 for which this is expected: a sort of Cayley tree. It is clear that, absent any “fine tuning,” the numbers N_{A}≠N_{B} on such a lattice. In the branching network 170, ten sites labeled A connect with eight sites labeled B only, and vice-versa; thus, the net spin in the ground state is S₀η/2π. Ten sites have a coordination number z=2, five sites have z=3, two sites have z=4, and one site has z=5. On a pure Cayley tree of branching number 2, half the sites are at the surface, and the number of A sites is precisely double that of the B sites. Complex fractal structures can be formed that constitute a similar three-dimensional lattice, such as from carbon foam.

Renormalized Coupling Constants

Given the antiferromagnetic A,B couplings J, one is able to calculate the effective ferromagnetic coupling constant J* between next-nearest neighbor spins as follows. Without loss of generality, we suppose the A's to be the majority sites, then eliminate the B's that separate the closest pairs of A's. Ising-like bonds provide a simple example; Heisenberg bonds are more realistic but also more complicated to evaluate, therefore for them we just quote the final result.

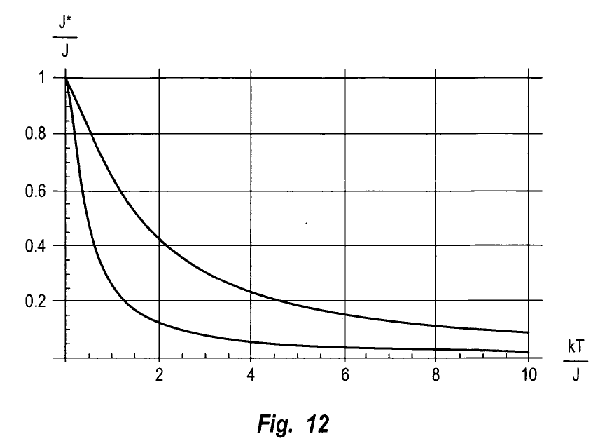

FIG. 12 is a graph showing the “effective” ferromagnetic coupling constant J*vs. kT, both in units of J. The upper curve in the graph is for the Ising model, Eq. (2), and the lower curve is for the Heisenberg model, Eq. (3), which are discussed hereafter.

In the Ising version, we evaluate <exp-JS_{B}(S_{A1}+S_{A2})/kTh, averaging over the values of the intervening B spin S_{B}=±1. We know this must result in a form Cexp(K*S_{A1}S_{A2}). The parameters C and K* are extracted as follows:
<e^{-JS}^{_{B}}^{(S}^{_{A1}}^{+S}^{_{A2}}^{)/kT}>_{B}=cosh²(J/kT)+S_{A1}S_{A2}sinh²(J/kT)=({square root over (cosh2J/kT))}e^{K·S}^{_{A1}}^{S}^{_{A2}} (1)
where tanhK*=tanh²K, and K*=J*/kT and K=J/kT. The ratio J*/J is a function of T:

$$\frac{J *}{J} = \frac{log ( cosh 2 K )}{2 K} ( Ising model . ) \qquad ( 2 )$$

The ratio J*/J decreases from a maximum 1 (at low T) to 0 (at high T) as shown in the graph of FIG. 12. The calculation for the Heisenberg model (spins 1/2) is more realistic but somewhat more involved. After setting η=1, each spin is written in the form S=(σₓ, σ_{y}, σ_{z})/2, where the σ's are the three Pauli matrices. The average <exp-JS_{B}_{^{g}}(S_{A1}+S_{A2})/kT>_{B} over the states of B must be re-expressed in the form C(K)e^{K*S}^{_{A1g}}^{S}^{_{A2}}. After some algebra we obtain:

$$\frac{J *}{J} = \frac{log ϕ ( K )}{K} ( Heisenberg ) , C ( K ) = {( ϕ ( K ) )}^{3 / 4} where ϕ ( K ) = \frac{{ⅇ}^{K} + 2 {ⅇ}^{- K / 2}}{3} . \qquad ( 3 )$$

This is also plotted in the graph of FIG. 12. All regular three-dimensional geometries (cubic, hcp, etc.) yield kT_{c}˜0.75 zJ* for the Ising model spins |S|=1 (where z is the coordination number of the lattice), while in the Heisenberg model for spins 1/2, one estimates kT_{c}˜0.5 zJ*. Supposing kT_{c}=O(100K), and arbitrarily setting z=3, Eq. (3) is inverted to estimate the magnitude of the original, “physical” antiferromagnetic coupling J between nearest-neighbor spins. We find it to be J/k_{B}=T_{c}/0.6˜167 K in the Heisenberg model, a small but reasonable value almost exactly what was calculated from first principles in the preceding section. Similarly, Eq. (2) can be inverted, which can be done analytically. Once the majority spins order at temperatures below T_{c}, the minority sublattice also orders but antiparallel to the majority. Thus, a net moment M that is proportional both to m₀|N_{A}-N_{B}| and to the order parameter, persists at all T<T_{c}.

Manipulation of Conductive and Magnetic Phases in a Semiconductor Strip Array

Reference is now generally made to FIG. 13-17 in describing various features and aspects of another embodiment of the present invention. As will be described, FIGS. 13-17 illustrate various aspects of a semiconductor lattice nanostructure architecture that is configured to exhibit distinct electrical and magnetic properties according to selective electron insertion into or removal of electrons from the architecture. Changing the physical phase of the electron lattice by changing the concentration of electrons in this manner gives rise to various possible applications, including amplifiers, memory elements, and especially high temperature superconductors.

FIG. 13 depicts a semiconducting strip array (“strip array”), generally designated at 210, according to one embodiment. The strip array 210 is formed on a substrate 212 by a plurality of strips 214 that are deposited on the substrate in the manner shown in FIG. 13. As shown, the strips 214 are deposited on the substrate 212 in a criss-cross pattern such that a plurality of strip intersections is formed on the substrate. In the present embodiment, the strip intersection architecture is substantially formed at right angles, though in other embodiments other angles can be defined (cf. FIGS. 4 and 5.) Note that only a portion of the strip array 210 is shown in FIG. 13; the areal size of the strip array can be configured to be much larger than what is shown here, and can be bounded by square, circular, or other boundary shapes.

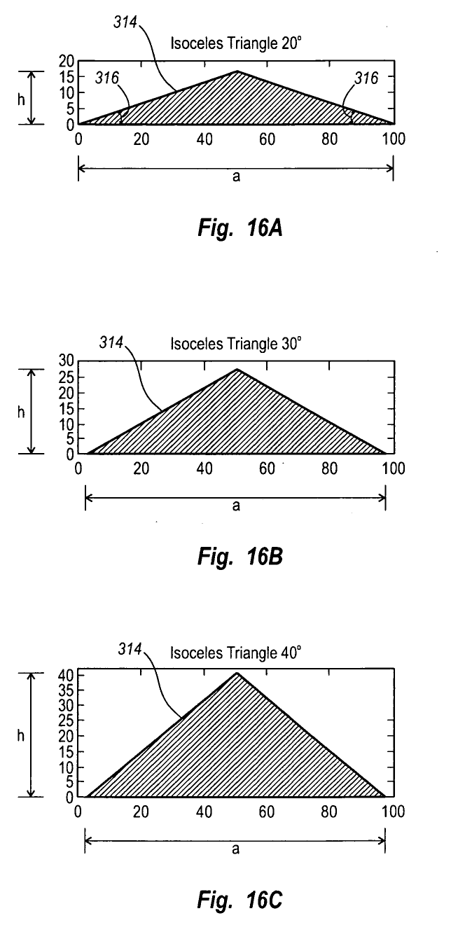

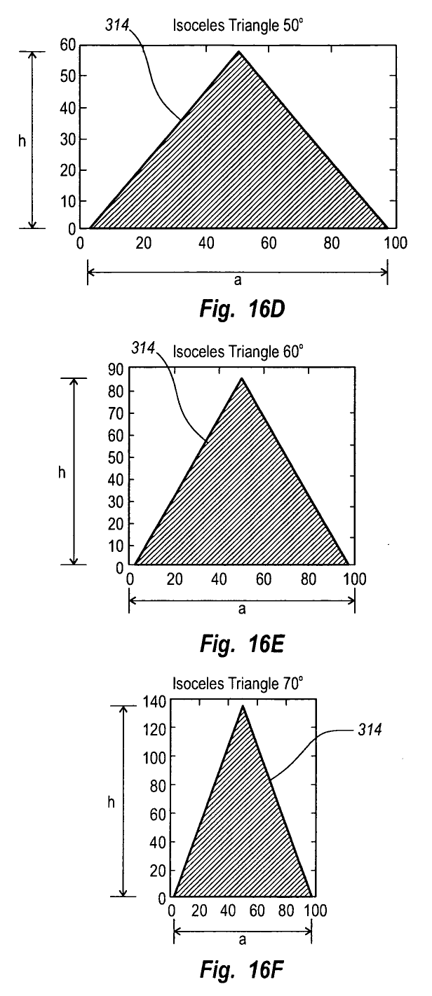

Each strip 214 can be characterized by a width “a,” and a depth “h,” with respect to the substrate 212 as shown in FIGS. 13 and 16A-F. Here the width, a, of each strip 214 is approximately 10 nanometers (nm), which is sufficiently small to enable the electron trapping processes described below to occur. In other embodiments, the range of a can vary from approximately 1 to 100 nm. Note that in the illustrated embodiment the widths and depths of the strips 214 are uniform, though strip dimensions can vary with respect to one another if desired or needed for a particular application.

The strips 214 are composed in the present embodiment of an intrinsic semiconductor, such as silicon (“Si”), though gallium arsenide (“GaAs”), indium antimonide (“InSb”), or any other suitable semiconducting materials that enable the functionality described below can also be used. This geometry, together with the introduction of electrons, each having a sufficiently small effective electron mass m*, enables non-destructive, desirable electronic and magnetic phase-specific characteristics to be exhibited even at elevated temperatures, including room temperature or higher in some cases. In particular, relatively high temperature superconductivity in the strip array is attainable in some embodiments.

Each intersection of the strips 214 shown in FIG. 13 defines primary electron-trapping nanodots, or sites, as indicated by the plurality of “A”-sites 216 shown at the strip intersections. A plurality of secondary electron-trapping “B”-sites 218 are also defined in the strip array 210. The B-sites 218 are interstitially positioned between the A-sites 216, and as such are defined on the strips 214 themselves, and not at the strip intersections. This configuration is of a type known as a bipartite lattice architecture.

The strip array 210 is subdivided into a plurality of cells 220, two of which are shown in phantom, on the substrate surface. Respective centers of adjacent cells 220 are spaced in the illustrated embodiment a distance of 2a, or approximately 20 nm, apart in the example where a=10 nm. As defined, each cell 220 includes the equivalent of one A-site 216 and 2 B-sites 218. Each cell 220 can be thought of as sharing half of each of four B-sites, as shown in FIG. 13, with adjacent cells. This configuration becomes useful in describing phase changes of electrons confined to the strip array 210, as discussed below. In another sense, each cell 220 can be thought of as an “artificial molecule” comprising A and B “atoms,” wherein the electron concentration therein can be selectively adjusted to enable the molecule to exhibit phase-specific properties.

Similar to previous embodiments, the strip array 210 is configured to selectively trap electrons within its lattice architecture. In more detail, the A-sites 216 and B-sites 218 have adistinct electron affinities with respect to one another, not because their respective potentials a differ, respective but by virtue of their relative positions and configurations within the strip array 210. As such, when electrons are introduced into the strip array 210 they will first occupy the primary electron trapping A-sites 216 in the array until all A-sites are filled. Such filling of A-sites only occurs as the combined result of the lattice geometry shown in FIG. 13 and of the coulomb repulsion between adjacent electrons that tends to keep them as far apart from one another as practicable. When all A-sites are filled, the introduction of additional electrons will result in the filling of the secondary electron trapping B-sites 218 as needed. In this way, selected concentrations of electrons can be injected into the strip array 210 and trapped at the A- and B-sites 216 and 218 in order to effect desired phase changes in the electrons occupying the strip array. Conceivably, up to 6 electrons could be trapped in each cell 220 as presently defined in FIG. 13, but the following discussion focuses on the insertion of from 0 to 3 electrons per cell.

The strip array architecture shown in FIG. 13 can be formed by precision processes, including electron beam lithography, molecular beam epitaxy, step and flash imprint lithography, and electron beam drilling to form an antidot lattice. In the case of electron beam drilling a solid layer (“film”) of suitable semiconductor material is deposited on the substrate, then selected portions thereof are drilled away by an electron drilling process until a suitable lattice structure, such as that shown in FIG. 13, remains.

Reference is now made to FIG. 14, which shows a simplified side view of a metal oxide semiconductor field effect transistor (“MOSFET”), generally indicated at 230. As shown, the MOSFET 230 includes a grounded 232 substrate on which the strip array 210, shown in FIG. 13, is deposited. The strip array 210 is formed on the substrate 232 using any of the processes described above as a part of the manufacturing process of the MOSFET 230.

An insulator 234 is deposited atop the strip array 210. A source 236, drain 238, and gate 240 are deposited atop the insulator, and terminals 242 are connected to each of the source and drain to make electrical contact with the ends of the strip array; and gate and ground are inserted to enable functionality of the MOSFET 230. In addition to the components explicitly set forth in FIG. 14, other layers or elements can be added to the MOSFET 230 as may be appreciated by those skilled in the art.

The MOSFET structure described herein and shown in FIG. 14 is utilized to enable electrons to be injected, or introduced, into the strip array 210, thereby creating an “electron gas” in the array that connects source to drain. This magnitude of electron concentration in the strip array can be controlled and modified over time by the gate and ground of the MOSFET structure in order to non-destructively and selectively change the electronic and/or magnetic, also collectively referred to herein as “electromagnetic,” properties of the strip array. In this way, the electron gas in the strip array can exhibit different phase characteristics according to its electron concentration, as will be seen. Introduction of the electrons into the strip array can occur via doping, e.g., ion implantation; electron tunneling via cap acitative means, or by the other suitable methods.

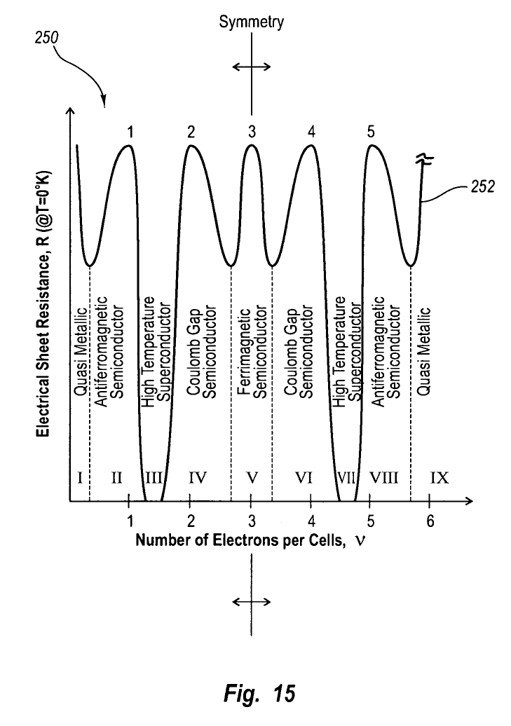

Reference is now made to FIG. 15, showing a phase diagram, generally indicated at 250, that charts the electrical resistance of the strip array 210 (FIG. 13) versus the number of electrons per cell 220; indicated by “v”, of the strip array at a temperature T=0 degrees Kelvin (absolute). A curve 252 is described on the phase diagram 250 to facilitate inspection of the relative variance of the strip array resistance as a function of electrons per cell. Note here that the points on the horizontal x-axis, corresponding to the number of electrons per cell v, where the electrical resistance vanishes or is at a maximum, for example, are given or shown at approximate numerical values. These values are approximate and can e.g., strip dimensions and compositions, etc. They are nonetheless stated here in the interest of further describing the present invention.

Beginning at the left vertical axis of the phase diagram 250, a first phase region I is shown wherein the electron concentration per cell of the strip array, v, falls between 0 and approximately 0.25. A non-integer v, as in 0.25, indicates that not all A-sites 216 in the strip array 210 (FIG. 13) are filled with electrons. Thus, as an average over the entire strip array 210, v equals approximately 0.25 in this first phase region I, corresponding to approximately 25% of all A-sites being filled. Near the border of phase region I, i.e. at v=0.25, the electrical resistance is relatively low. At this electron concentration, the strip array 210 exhibits quasi-metallic characteristics, as noted on the phase diagram 250.

In a second phase region II, v ranges from approximately 0.25 to 1.25. Electrical resistance in phase region II tends to relatively increase approaching v=1 where antiferromagnetic phase properties dominate. Phase region II is thus considered an antiferromagnetic semiconductor phase for the strip array v, wherein at v=1 all A sites are occupied, the B sites are empty, and nearest-neighbor A sites have opposite election spin orientations. Here, it is seen that the strip array 210 exhibits both a magnetically-related property (antiferromagnetism) and an electrically-related insulator property. As electron configuration moves away from v=1 this phase becomes electronically similar to that of an increasingly doped insulator and its magnetic order and electrical resistance both decrease, as shown by the curve 252.

As more electrons are introduced into the strip array 210, v increases into phase region III defined by v between approximately 1.2 and 1.5. In this phase region III, the strip array exhibits superconductivity characteristics and, depending on the semiconductor strip dimensions and composition, these superconductivity characteristics are exhibited at elevated temperatures relative to traditional superconductivity conditions. These elevated temperatures may be as low as 1° K. or as high as 600° K., somewhat similar to temperatures possible with high-T_{c} superconductors based on CuO₂. Thus, the strip array 210 can be configured to artificially simulate a high temperature superconductor without being composed of traditional superconductive materials, in accordance with one embodiment of the present invention. This feature holds significant promise in present and future applications where high temperature superconductivity is desired or required, either free-standing or within the bounds of an electronic circuit.

At v values between approximately 1.5 and 2.75, phase region IV is defined, wherein the strip array 210 exhibits semiconductor characteristics, owing to the effects of coulomb repulsion within the cells 220 and the filling of electron energy bands at precisely v=2.

Phase region V is defined by approximate v values from 2.75 to 3.25. In this region, the strip array 210 has a per-cell electron concentration sufficient to enable the strip array to exhibit ferromagnetic (magnetic property) and, at or near v=3, insulating or semiconductor (electrical property) characteristics.

The strip array architecture of the present embodiment (FIG. 13) exhibits an approximate symmetry approximately about v=3. This symmetry is based on an approximation to the electron states known as the tight-binding approximation, but it is evocative of the physical situation. On either side of this electron concentration, similar phase characteristics are exhibited, according to the relation v=6-v. For example, inspection of the phase diagram 250 will show that v=1.25 corresponds to v=4.75 (6-1.25=4.75; 6-4.75=1.25). Thus, the phase regions VI (coulomb gap semiconductor at approximately 3.25<v<4.50), VII (high temperature superconductor at approximately 4.50<v<4.75), VIII (antiferromagnetic semiconductor at approximately 4.75<v<5.75), and IX (quasi-metallic at approximately v>5.75) symmetrically correspond with the phase characteristics exhibited at phase regions IV, III, II, and I, respectively. Note that this is an approximate symmetry, for in addition to tight-binding it assumes an electron-hole symmetry that is easily broken. In practice, however, it should be anticipated that it will be easiest to inject as few electrons as possible into the strip array, hence electron insertion in the range 0<v<3 may be quite sufficient for most applications.

The strip array architecture is such in the present embodiment that it acts as an electrical insulator at v=integer values of 0, 1, 2, 3, 4, 5 and 6, as is seen by inspection of the curve 252 in the phase diagram 250 of FIG. 15. Near those integers the array acts as a doped insulator or semiconductor.

It is noted here that, depending on the strip array configuration, some of the electron concentrations represented by the various phase regions shown in the phase diagram 250 may not be easily achievable for the strip array under all conditions. As such, in the present embodiment, some phase regions, e.g., phase regions VI, VII, VIII and IX, may be considered theoretically possible, and may also be considered achievable in actuality if proper strip array configurations are achieved. In any event, it is appreciated that, due to the above symmetry of the strip array architecture, the same phase characteristics that are possible in phase regions VI, VII, VIII, and IX are correspondingly achievable in phase regions IV, III, II, and I, respectively, at relatively lower and more easily achieved electron concentrations.

The strip array 210, in the high temperature superconductor phase regions III and VII, artificially mimics the lattice structure of copper oxide, a known relatively high temperature superconductor, in accordance with principles of the present invention. Copper oxide, as a relatively high temperature superconductor, has an electron hole concentration of approximately 25% (that is, in addition to the 1 hole per copper ion that allows the copper to exhibit a net spin of ½). This hole content corresponds to an electron concentration, v, of about 4.75 in the present strip array architecture, as shown in the phase diagram 250:1 on the “copper” A site of FIG. 13 and 1.875 on each “oxygen” B site. By the above-described symmetry, v=4.75 is equivalent by symmetry to v=1.25 An electron concentration of 1.25 is not achievable via chemical means in traditional CuO₂-based materials but is readily achievable in the strip array 210 at an appropriate gate voltage. As such, the strip array configuration of embodiments of the present invention appears to represent a significant advancement in applications of high temperature superconductivity.

In greater detail, the high temperature superconductor phase of the strip array 210 is exhibited at v=1.25 (4.75) due to three parameters that, aside from the confining the geometry itself, can be considered to substantially affect this phase: semiconductor strip cross sectional thickness, distance between the strips in the array, and the effective mass (“m*”) of the charge carriers, e.g., electrons. Strip array configurations that minimize the electrons' effective mass are desirable because relatively small effective mass equates to relatively more energetic electrons, thereby shifting the unit of energy upwards. For example, use of InSb for the strips 214 (FIG. 13) results in desirable (small) electron effective mass properties. For practical reasons intrinsic silicon or GaAs are preferred in one embodiment for the composition of the strips 214. Calculated values of the critical temperature T_{c} of the superconducting phase range as high as room temperature or above are possible in one embodiment provided the strip cross section and strip spacing dimensions are in an appropriate range from 5 to 15 nm and the strip geometry is appropriately fine-tuned. Fine tuning of the strip geometry includes the precise shape of the antidots (square cutouts vs. circle cutouts, and best ratio of strip dimensions to strip spacing) in the antidot lattice, the purity of strip materials used, the shape of the strips (rectangular vs. cylindrical vs. triangular cross-section, as discussed below) and in the case of silicon, the best orientation of the crystal axes relative to the plane of the substrate, to ensure the smallest effective mass, m*, component of the mass tensor lies in the plane.

The strip array architecture, either as part of or independent from the MOSFET described above, can be employed in various possible applications, including memory cells, amplifiers, spintronics applications, and as mentioned, a wide variety of possible applications involving high temperature superconductivity. In a memory cell application, for instance, a small strip array could be held at a substantially insulating phase, such as when v=1, to indicate a 0 or 1 digital bit value. The phase could then be changed as described above to make v=1.25, a superconducting phase, when the memory cell is reprogrammed or erased to indicate a corresponding 1 or 0 digital bit value. In spintronics, the strip array architecture could be employed to receive by injection a stream unpolarized electrons and eject a stream of spin-polarized electrons having predominantly the same spin. That is, electrons entering at the source are unpolarized, but a majority of those exiting the drain have, on average, the same spin polarization. Such a net-polarized electron stream (“spin filter”) can be valuable in spintronics-related applications employing solid state devices, for instance. In an amplifier application, the strip array can be phase-modified to selectively alternate between high and low electrical resistance phases so as to be suitable for signal or power amplifier applications. These and other possible applications are therefore contemplated as part of the present invention.

Reference is now made to FIGS. 16A-F. It has been discovered that the energy of an electron in a strip 314 of the strip array, such as the array 210 in FIG. 13, is related to the cross sectional shape of the strip. As such, in one example embodiment the cross sectional shape of the strip 314 described above can be configured so as to desirably maximize the energy of electrons that are injected into the strip array. One achievable and beneficial cross sectional strip shape has been shown to be triangular. Indeed, as shown in FIGS. 16A-16F, the triangular shape of the strip 314 can be defined by one of a variety widths, “a,” heights, “h” and inside angles 316. Generally, the “flatter” the triangle shape, i.e., the smaller the bottom inside angles 316 are, the more energy the electron within the strip 314 can possess and thus the higher the unit of energy in the array.

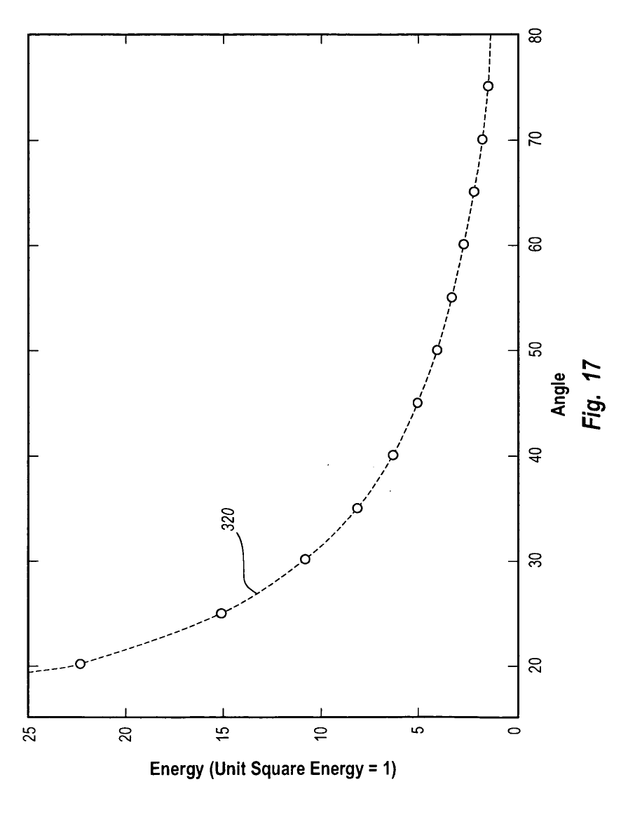

The above relationship between triangle strip shape and electron energy can be seen in FIG. 17, which is a graph charting electron energy as a function of the magnitude of the bottom inside angles 316 of the strips 314 in FIGS. 16A-16F. As expected, as the inside angles decrease, the electron energy desirably increases.

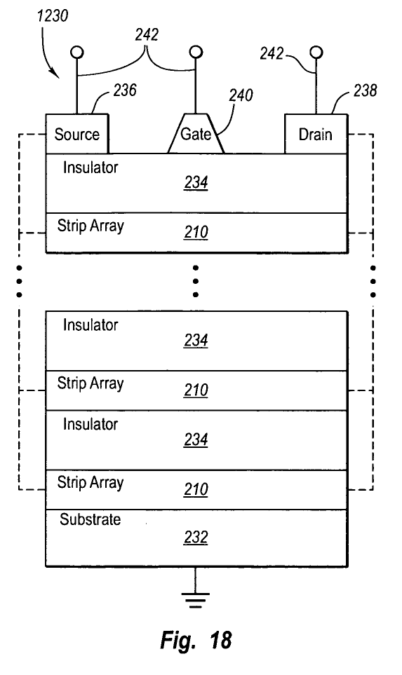

Reference is now made to FIG. 18, which depicts a MOSFET device architecture employing elements of the present invention, according to yet another embodiment. As shown, FIG. 18 includes a MOSFET 1230, including the grounded substrate 232, source 236, drain 238, gate 240, and terminals 242, similar to the MOSFET shown in FIG. 14. In contrast to the MOSFET 230, however, the MOSFET 1230 in FIG. 18 includes successive layers of the strip array 210 and insulator 234 deposited on the substrate 232 in a sandwich configuration and connected at the ends, as shown by the phantom lines in FIG. 18, to the respective source and drain so as to be electrically in parallel. The number of sandwiched layers can be varied as may be needed or desired according to the intended application. The sandwiched strip array layers 210 can increase the effect of the strip arrays in their various phase configurations: for example, ten sandwiched strip array layers can carry in parallel approximately ten times the amount of current as a single strip array when the arrays are in the superconducting phases III or VII. Thus, enhancements of the strip array electronic and magnetic phase effects are possible with the sandwiched configuration shown here. The sandwich configuration also allows relatively higher gate voltages to be used during operation.

The strips 314 can be deposited in the shape shown in FIGS. 16A-16F using known deposition techniques, such as sputtering. In addition to triangles, other cross sectional strip shapes can be defined, including square, rectangular, circular, etc.

The present invention may be embodied in other specific forms without departing from its spirit or essential characteristics. The described embodiments are to be considered in all respects only as illustrative, not restrictive. The scope of the invention is, therefore, indicated by the appended claims rather than by the foregoing description. All changes that corner within the meaning and range of equivalency of the claims are to be embraced within their scope.

What is claimed is:

1. A strip array architecture, comprising:
a substrate; and
a plurality of strips deposited on the substrate in an intersecting pattern to define a strip array, wherein the strip array defines primary electron trapping sites and secondary electron trapping sites, and wherein the strip array is configured to exhibit distinct electromagnetic properties according to a selective concentration of electrons inserted into the primary and secondary electron trapping sites.

2. The strip array architecture as defined in claim 1, wherein the primary electron trapping sites are defined at the intersections of the strips, and wherein the secondary electron trapping sites are defined at portions of the strips that are between the strip intersections.

3. The strip array architecture as defined in claim 2, wherein the primary and secondary electron sites are organized into cells, wherein each cell includes a primary electron trapping site and at least a portion of a plurality of secondary electron trapping sites.

4. The strip array architecture as defined in claim 1, wherein the width of the strips and spacing between the strips is selected so as to maximize energy of the electrons inserted into the strip array.

5. The strip array architecture as defined in claim 4, wherein the strip spacing is approximately twice the strip width.

6. The strip array architecture as defined in claim 1, wherein the strip material is selected or oriented so as to minimize the effective mass of the electrons inserted into the strip array.

7. The strip array architecture as defined in claim 6, wherein the strip material is an intrinsic semiconductor.

8. The strip array architecture as defined in claim 1, wherein the strip intersections are defined at substantially right angles.

9. The strip array as defined in claim 1, wherein the strip array exhibits electrical semiconductivity at a first electron concentration in the strip array, and wherein the strip array exhibits electrical superconductivity at a second electron concentration, and wherein the strip array exhibits electrical insulating characteristics at a third electron concentration.

10. The strip array as defined in claim 1, wherein the strip exhibits antiferromagnetism at the first electron concentration, and wherein the strip array exhibits ferrimagnetism at another electron concentration.

11. The strip array as defined in claim 1, wherein the strip array mimics the structure of copper oxide at the superconductive second electron concentration.

12. A method for changing the electromagnetic properties of a semiconductor strip array including a plurality of intersecting strips of semiconductor material deposited on a substrate, the intersections of the strips defining primary electron trapping sites, the portions of the strips between the strip intersections defining secondary electron trapping sites, the method comprising:
inserting a first quantity of electrons into the strip array so that at least a portion of the primary electron trapping sites are occupied with the electrons, and such that the strip array exhibits a first electromagnetic phase; and
altering the amount of electrons in the strip array to a second quantity of electrons so that the strip array exhibits a second electromagnetic phase.

13. The method for changing as defined in claim 12, wherein inserting the first quantity of electrons occupies each of the primary electron trapping sites and at least some of the secondary electron trapping sites.

14. The method for changing as defined in claim 12, wherein one of the first and second electromagnetic phases is a superconductive phase.

15. The method for changing as defined in claim 12, wherein the first quantity of electrons inserted into the strip array are spin unpolarized, and wherein the method further comprises:
outputting a stream of electrons from the strip array, the outputted electrons a net polarized spin.

16. The method for changing as defined in claim 12, wherein the process by which the strip array is formed is selected from the group consisting of flash imprint lithography, electron drilling, molecular beam epitaxy and electron beam lithography.

17. The method for changing as defined in claim 12, wherein the strip array is defined by an antidot lattice.

18. A MOSFET structure, comprising:
a substrate;
a semiconductor strip array including intersecting strips of semiconductor material deposited on the substrate, the strip array defining primary electron trapping sites at the strip intersections and secondary electron trapping sites at portions of the strips between the strip intersections;
an insulator included above the strip array; and
a source, a drain, and a gate included above the insulator;
wherein the strip array exhibits a first electromagnetic phase when a first electron concentration is present in the electron trapping sites and a second electromagnetic phase when a second electron concentration is present in the electron trapping sites.

19. The MOSFET structure as defined in claim 18, wherein the strip array is divided into cells, and wherein each cell includes one primary electron trapping site and shares secondary electron trapping sites with adjacent cells.

20. The MOSFET as defined in claim 19, wherein the strip array is configured such that the first or the second electromagnetic phases exhibit at least one of the following: a quasi-metallic phase, a semiconductor phase, an antiferromagnetic phase, a superconducting phase, and a ferrimagnetic phase.

21. The MOSFET as defined in claim 20, wherein superconductivity can be achieved in the strip array at an electron concentration of approximately 1.25 electrons per cell.

22. The MOSFET as defined in claim 21, wherein electron concentrations per cell greater than a predetermined value exhibit phases that are symmetrically similar to corresponding phases of electron concentrations per cell below the predetermined value.

23. The MOSFET as defined in claim 22, wherein the predetermined value is approximately 3 electrons per cell, and wherein symmetrical superconductivity exists at electron concentrations of approximately 1.25 and 4.75 electrons per cell.

24. The MOSFET as defined in claim 23, wherein the superconducting phase of the strip array occurs at room temperature.

25. The MOSFET as defined in claim 24, wherein the strips are composed substantially of silicon.

26. The MOSFET structure as defined in claim 25, wherein the strip array is a nanostructure, and wherein the width of each strip is approximately 10 nanometers.

27. The MOSFET as defined in claim 26, wherein the cross sectional shape of each strip is substantially triangular.

28. The MOSFET as defined in claim 27, wherein the MOSFET is employed as a memory element, a signal amplifier, or a power amplifier.

29. The MOSFET as defined in claim 28, wherein the electrons are introduced into the electron trapping sides by doping, electron tunneling, or via capacitative effects.

30. The MOSFET as defined in claim 29, wherein at least some of the intersecting strips terminate vertically below the source or drain and are operably connected to both the source and the drain.

31. A MOSFET structure, comprising:
a substrate;
a semiconductor and insulator stack deposited on the substrate, including:
a plurality of semiconductor strip array layers, each layer including intersecting strips of semiconductor material, each strip array layer defining primary electron trapping sites at the strip intersections and secondary electron trapping sites at portions of the strips between the strip intersections; and
a plurality of insulating layers interposed between successive semiconductor strip array layers; and
a source, a drain, and a gate included above the semiconductor and insulator stack;
wherein each strip array layer exhibits a first electromagnetic phase when a first electron concentration is present in the electron trapping sites and a second electromagnetic phase when a second electron concentration is present in the electron trapping sites.

32. The MOSFET structure as defined in claim 31, wherein an insulating layer is directly below the source, drain, and gate, and wherein one of the plurality of strip array layers is directly above the substrate.

33. The MOSFET structure as defined in claim 32, wherein the strip array layers are connected in parallel between the source and the drain.

34. The MOSFET structure as defined in claim 33, wherein at least one of the plurality of strip array layers is defined by an antidot lattice.
